(19) United States
(12) Patent Application Publication
(10) Pub. No.: US 2007/0145598 A1
(43) Pub. Date: Jun. 28, 2007

(54) METHOD OF FORMING A METAL INTERCONNECTION IN A SEMICONDUCTOR DEVICE

(76) Inventor: Jin Ah Kang, Gyeonggi-do (KR)

Correspondence Address: SHERR & NOURSE, PLLC, 620 HERNDON PARKWAY, SUITE 200, HERNDON, VA, 20170, US

(21) Appl. No.: 11/613,751

(22) Filed: Dec. 20, 2006

(30) Foreign Application Priority Data
Dec. 26, 2005 (KR) 10-2005-0129754

(51) Int. Cl. H01L 23/48

(52) U.S. Cl. 257/774

(57) ABSTRACT

A method includes at least one of: forming a metal interconnection in a semiconductor device; forming an inter-metal dielectric layer over a substrate and/or a lower metal layer; forming a photoresist pattern over an inter-metal dielectric layer; forming a via hole by selectively etching an inter-metal dielectric layer using a photoresist pattern as a mask; forming an ionization layer in a via plug by ion implantation on a sidewall of a via hole; forming a barrier metal layer and a via plug in the via hole; and/or forming a metal interconnection. In embodiments, a barrier metal layer may include titanium nitride and/or a via plug may include tungsten.

The present application claims priority under 35 U.S.C. 119 and 35 U.S.C. 365 to Korean Patent Application No. 10-2005-0129754 (filed on Dec. 26, 2005), which is hereby incorporated by reference in its entirety.

### BACKGROUND

Highly integrated semiconductor device may have multi-layered structures and may include a multi-layer interconnections. In multi-layer interconnections, interconnection layers and insulating layers may be alternately formed on upper portions of a semiconductor substrate that includes a circuit device. Interconnection layers may be isolated from each other by insulating layers. Interconnection layers may be electrically connected to each other through vias.

Alternate interconnections may be realized in semiconductor devices with multi-layer interconnections. The degree of freedom may be improved when designing circuits of semiconductor devices. The degree of integration of semiconductor devices may be enhanced. The length of a metal interconnection may be minimized reduced, which may reduce a delay time, which may enhance the operational speed of a semiconductor device.

A metal interconnection is illustrated with reference to FIG. 1. A contact plug formed between metal interconnections may include a tetraethyl orthosilicate (TEOS) film coated over an upper part of a metal interconnection 10. A TEOS film may form inter-metal dielectric layer 20. An upper metal layer may be connected to a lower metal layer by forming via hole 30. Via hole 30 may be formed by coating a photoresist film over inter-metal dielectric layer 20 and then performing an exposure process, a development process, and/or an etching process to form via hole 30.

Barrier metal layer 40 may be formed having a predetermined thickness. Tungsten may be filled into via hole 30. Tungsten may be planarized (e.g. through chemical mechanical polishing (CMP)) to form via plug 50.

During formation of metal interconnection having a line width of 0.18 um or less, various complications may occur. An inter-metal dielectric layer may include a low-k-material, which may provide for relatively low metal interconnection resistance and/or relatively low capacitance between metal interconnections. It may be difficult to reduce the thickness of inter-metal dielectric layers between metal interconnections to maintain interconnection capacitance at a reasonable level. In other words, if the size of a via hole is relatively small and the thickness of an inter-metal dielectric layer is relatively thick, barrier metal layer 40 may be formed irregularly. Voids 51 may occur in tungsten 50 from a chemical vapor deposition (CVD) gap when a via plug is formed, as illustrated in FIG. 2.

As a result of voids 51, contact resistance of a via hole may increase. As a result of voids 51, a short phenomenon may occurs in a metal interconnection, which may prevent a semiconductor device from being driven. Voids 51 may cause the reliability of a semiconductor device to be compromised.

### SUMMARY

Embodiments relate to semiconductor manufacturing technology. Embodiments relate to a method of forming a metal interconnection in a semiconductor device, in which an ionization layer may be formed at a sidewall of a via hole through ion implantation. An ionization layer may be form while forming a via hole for an interconnection between a lower metal layer and an upper metal layer, in accordance with embodiments. An ionization layer may prevent a barrier metal layer from being formed irregularly, in embodiments. An ionization lay may prevent voids from being created in a tungsten gap fill, in embodiments.

In embodiments, a method includes at least one of: forming a metal interconnection in a semiconductor device; forming an inter-metal dielectric layer over a substrate and/or a lower metal layer; forming a photoresist pattern over an inter-metal dielectric layer; forming a via hole by selectively etching an inter-metal dielectric layer using a photoresist pattern as a mask; forming an ionization layer in a via plug by ion implantation on a sidewall of a via hole; forming a barrier metal layer and a via plug in the via hole; and/or forming a metal interconnection. In embodiments, a barrier metal layer may include titanium nitride and/or a via plug may include tungsten.

### BRIEF DESCRIPTION OF DRAWINGS

FIG. 1 is a sectional view of a semiconductor device.

FIG. 2 is a sectional view showing defects occurring in a semiconductor device.

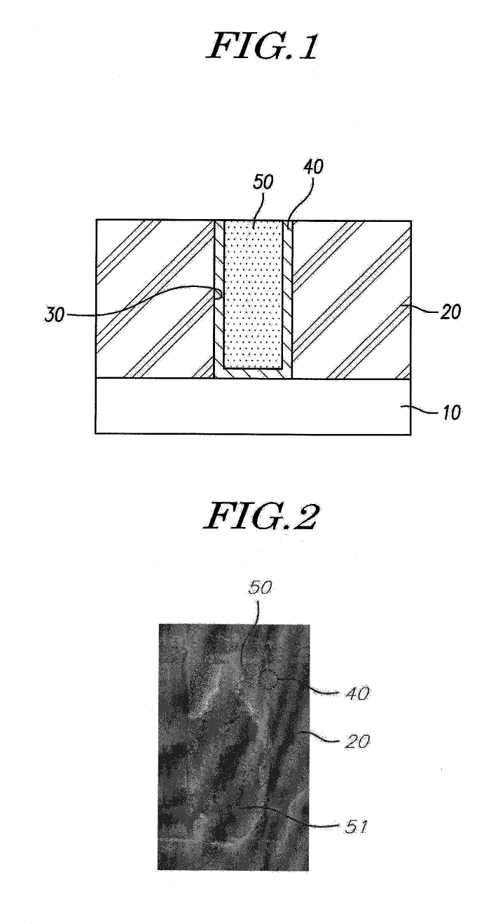

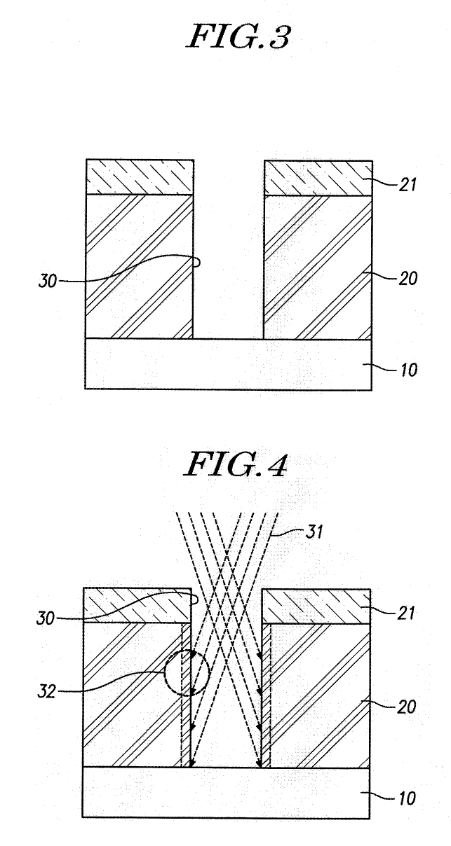

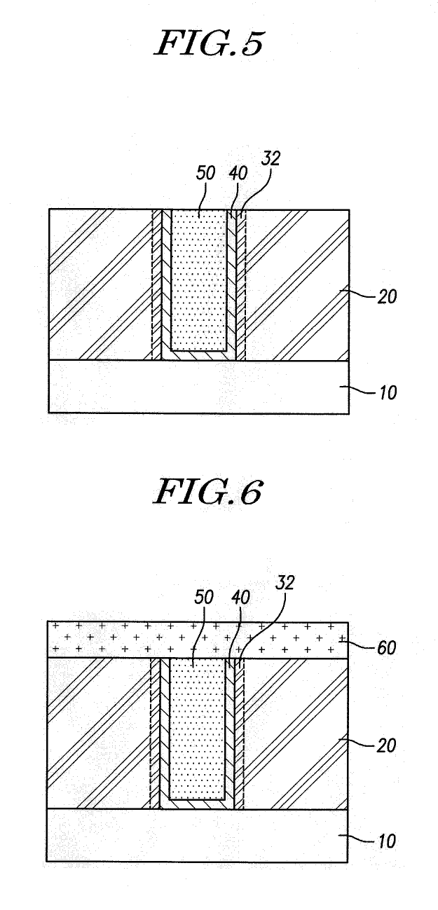

Example FIGS. 3 to 6 are sectional views sequentially showing a method of forming a metal interconnection of a semiconductor device, according to embodiments.

### DETAILED DESCRIPTION

Example FIGS. 3 to 6 are sectional views illustrating methods of forming metal interconnections in a semiconductor device, according to embodiments. As illustrated in FIG. 3, inter-metal dielectric layer 20 may be coated over substrate 10 and/or over a lower metal layer. Inter-metal dielectric layer 20 may have a predetermined thickness. In embodiments, Inter-metal dielectric layer 20 may be formed by performing an atmospheric pressure chemical vapor deposition (APCVD) process, a low pressure chemical vapor deposition (LPCVD) process, and/or a plasma enhanced chemical vapor deposition (PECVD) process with respect to an oxide layer (SiO₂) using a silane gas (SiH₄).

Photoresist pattern 21 may be formed over inter-metal dielectric layer 20 through a photo process. Inter-metal dielectric layer 20 may be selectively etched using photoresist pattern 21 as a mask to form via hole 30.

As illustrated in FIG. 4, a via plug ion implantation process 31 may be performed on via hole 30 using photoresist pattern 21 as a mask, in accordance with embodiments. Sidewalls of via hole 30 may be ionized through a via plug ion implantation process. Ionization layer 32 may be formed by implanting impurities into the sidewalls of via hole 30.

In embodiments, ionization layer 32 may be formed by depositing a polysilicon layer inside via hole 30 and then implanting impurities into the polysilicon layer. For example, after forming via hole 30 in inter-metal dielectric layer 20, as shown in FIG. 3, a polysilicon layer may be linearly deposited inside via hole 30. Phosphine (PH₃) and/or phosphorus (P) ions may implanted into a portion of a polysilicon layer on sidewalls of via hole 30 using a via plug ion implantation process, according to embodiments. In embodiments, an ion-implantation layer may serve as a conductive ionization layer 32 at sidewalls of via hole 30.

As illustrated in FIG. 5, barrier metal layer 40 may be formed over substrate 10 inside via hole 30. In embodiments, barrier metal layer 40 includes titanium nitride (TiN). In embodiments, since the sidewalls of via hole 30 are ionized so that ionization layer 32 is formed, adhesive force may be optimized. In embodiments, barrier metal layer 40 may be uniformly formed. Tungsten (W) may be deposited in via hole 30 over barrier metal layer 40 to form via plug 50.

In embodiments, tungsten 50 may be a contact material. Tungsten 50 may be part of a silicon integrated circuit having a minimum line width less than approximately 1 μm. In embodiments, tungsten 50 may have a relatively low resistivity (e.g. 5.3Ω·cm) and/or a relatively low coefficient of thermal expansion (e.g. 4.6·10−6/° C.). In embodiments, the thermal expansion characteristics of tungsten 50 may be approximately the same as silicon.

In embodiments, tungsten 50 is a metal having a relatively high melting point, which may prevent electron emigration and/or may be employed in a high temperature process. In embodiments, since tungsten deposited through a chemical vapor deposition (CVD) process may have a relatively high step coverage, CVD deposited tungsten may have some superior properties compared to tungsten deposited by an evaporation depositing process and/or a sputtering process.

In embodiments, since an ionization layer is formed at the sidewalls of via hole 30 through via plug ion implantation process 31, barrier metal layer 40 may be formed uniformly. If barrier metal layer 40 is formed uniformly, voids may be prevented when tungsten is deposited, in accordance with embodiments. In embodiments, voids may be prevented even if an inter-metal dielectric layer is relatively thick and/or the size of via hole 30 is relatively small.

A CMP process may be performed, which may remove excessive tungsten excessively from the surface of via plug 50. As illustrated in FIG. 6, metal layer 60 may form a metal interconnection over via plug 50 (e.g. through a CVD process and/or a PVD process). Metal layer 60 may be selectively etched (e.g. through a plasma etching process) to form metal interconnection 60.

According to embodiments, an ionization layer may be formed at sidewalls of a via hole through a via plug ion implantation process. An ionization layer may allow for a barrier metal layer to be formed uniformly, in accordance with embodiments. In embodiments, an ionization layer may prevent voids from being created when tungsten (W) is deposited in a via hole. In embodiments, voids may be prevented when tungsten (W) is deposited, which may optimize interconnection characteristics of a semiconductor device.

While the invention has been shown and described with reference to certain preferred embodiments thereof, it will be understood by those skilled in the art that various changes in form and details may be made therein without departing from the spirit and scope of the invention as defined by the appended claims.

What is claimed:

1. A method comprising:
forming a dielectric layer over a substrate;
forming a via hole in the dielectric layer; and
forming an ionization layer on sidewalls of the via hole.

2. The method of claim 1, wherein the method forms a metal interconnection in a semiconductor device.

3. The method of claim 1, wherein the dielectric layer is an inter-metal dielectric layer.

4. The method of claim 1, wherein the dielectric layer comprises a lower metal layer.

5. The method of claim 1, wherein said forming a via hole comprises:
forming a photoresist pattern over the dielectric layer;
selectively etching the via hole in the dielectric layer using the photoresist pattern as a mask; and
removing the photoresist pattern.

6. The method of claim 1, wherein said forming an ionization layer comprises performing a via plug ion implantation process on sidewalls of the via hole.

7. The method of claim 1, comprising forming a barrier metal layer in the via hole over the ionization layer.

8. The method of claim 7, comprising forming a via plug in the via hole over the barrier layer.

9. The method of claim 8, comprising forming a metal interconnection over the via plug.

10. The method of claim 8, wherein the via plug includes tungsten.

11. The method of claim 8, wherein the via plug is formed by chemical vapor deposition.

12. The method of claim 9, wherein the barrier metal layer comprises titanium nitride.

13. An apparatus comprising:
a dielectric layer formed over a substrate;
a via hole formed in the dielectric layer; and
an ionization layer formed on sidewalls of the via hole.

14. The apparatus of claim 13, wherein the apparatus is a metal interconnection formed in a semiconductor device.

15. The apparatus of claim 13, wherein the dielectric layer is an inter-metal dielectric layer.

16. The apparatus of claim 13, wherein the dielectric layer comprises a lower metal layer.

17. The apparatus of claim 13, wherein said ionization layer is formed by performing a via plug ion implantation process on sidewalls of the via hole.

18. The apparatus of claim 13, comprising a barrier metal layer formed in the via hole over the ionization layer.

19. The apparatus of claim 18, wherein:
a via plug is formed in the via hole over the barrier layer;
the via plug includes tungsten;
the via plug is formed by chemical vapor deposition; and
a metal interconnection is formed over the via plug.

20. The apparatus of claim 18, wherein the barrier metal layer comprises titanium nitride.
